(19) United States
(12) Patent Application Publication
(10) Pub. No.: US 2026/0271320 A1
(43) Pub. Date: Sep. 10, 2026

(54) SEMICONDUCTOR DEVICE

(71) Applicant: SAMSUNG ELECTRONICS CO., LTD., Suwon-si (KR)

(72) Inventors: JONGHAK KIM, Suwon-si (KR); KANG-SUK SEO, Suwon-si (KR); SANG SEOP SHIM, Suwon-si (KR); JONG WON JANG, Suwon-si (KR)

(73) Assignee: SAMSUNG ELECTRONICS CO., LTD., Suwon-si (KR)

(21) Appl. No.: 19/332,675

(22) Filed: Sep. 18, 2025

(30) Foreign Application Priority Data
Mar. 5, 2025 (KR) 10-2025-0028498

(51) Int. Cl. H10D 18/65; H10D 18/01; H10D 62/832

(52) U.S. Cl. CPC H10D 18/65; H10D 18/01; H10D 62/8325

(57) ABSTRACT

A semiconductor device includes: a first semiconductor layer having a first conductivity type; a second semiconductor layer having a second conductivity type and on the first semiconductor layer; a third semiconductor layer having the first conductivity type and on the second semiconductor layer; a gate electrode on the third semiconductor layer; a semiconductor pattern on the third semiconductor layer and having the second conductivity type; an anode electrode on the semiconductor pattern; and a cathode electrode on a lower surface of the first semiconductor layer. The semiconductor pattern includes a first pattern on a lower surface of the anode electrode and including a first semiconductor material having a first energy band gap, and a second pattern between the first pattern and the third semiconductor layer, the second pattern including a second semiconductor material having a second energy band gap greater than the first energy band gap.

### CROSS-REFERENCE TO RELATED APPLICATION

This application claims priority under 35 U.S.C. §119 to Korean Patent Application No. 10-2025-0028498, filed on Mar. 5, 2025, in the Korean Intellectual Property Office, the disclosure of which is incorporated by reference herein in its entirety.

### BACKGROUND

### 1. Field

The present disclosure relates to a semiconductor device.

### 2. Description of the Related Art

In modern society, semiconductor devices are closely related to our daily lives. In particular, the importance of power semiconductor devices used in various fields such as transportation (e.g. electric vehicles, railways, and electric trams), renewable energy systems (e.g. solar power generation and wind power generation), and mobile devices is gradually increasing. Power semiconductor devices are semiconductor devices used to handle high voltage or high current, and perform functions such as power conversion and control in large power systems or high-power electronic devices. Power semiconductor devices have high durability and the ability to handle high power, allowing them to handle large amounts of current and withstand high voltages. For example, power semiconductor devices may handle voltages from hundreds to thousands of volts and currents from tens to thousands of amperes. Power semiconductor devices may improve the efficiency of electrical energy by minimizing power loss. Additionally, power semiconductor devices may operate stably even in environments such as high temperatures.

These power semiconductor devices may be classified by material, for example, SiC based and GaN based power semiconductor devices are available. By manufacturing power semiconductor devices using SiC or GaN instead of existing silicon wafers (Si wafers), the shortcomings of silicon, such as unstable characteristics at high temperatures, may be complemented. SiC power semiconductor devices have high temperature resistance and low power loss, making them suitable for electric vehicles and renewable energy systems. Among SiC power semiconductor devices, semiconductor devices with a super junction structure are widely used to improve the trade-off between the forward characteristics and breakdown voltage of power semiconductor devices.

### SUMMARY

One or more example embodiments of the present disclosure provide a semiconductor device whose reliability may be improved.

.

According to an aspect of the disclosure, a semiconductor device includes: a first semiconductor layer having a first conductivity type; a second semiconductor layer on the first semiconductor layer, the second semiconductor layer having a second conductivity type that is different from the first conductivity type; a third semiconductor layer on the second semiconductor layer, the third semiconductor layer having the first conductivity type; a gate electrode on the third semiconductor layer; a semiconductor pattern on the third semiconductor layer, the semiconductor pattern having the second conductivity type; an anode electrode on the semiconductor pattern; and a cathode electrode on a lower surface of the first semiconductor layer, wherein the semiconductor pattern includes: a first pattern on a lower surface of the anode electrode, the first pattern including a first semiconductor material having a first energy band gap; and a second pattern between the first pattern and the third semiconductor layer, the second pattern including a second semiconductor material having a second energy band gap greater than the first energy band gap.

According to an aspect of the disclosure, a semiconductor device includes: a first semiconductor layer having a first conductivity type; a second semiconductor layer on the first semiconductor layer, the second semiconductor layer having a second conductivity type that is different from the first conductivity type; a third semiconductor layer on the second semiconductor layer, the third semiconductor layer having the first conductivity type; a gate electrode on the third semiconductor layer; a semiconductor pattern on the third semiconductor layer, the semiconductor pattern having the second conductivity type, wherein the semiconductor pattern includes: a first element which is a semiconductor element; and a second element; an anode electrode on the semiconductor pattern; and a cathode electrode on a lower surface of the first semiconductor layer, wherein the semiconductor pattern includes: a first pattern; and a second pattern between the first pattern and the third semiconductor layer, wherein a content (at%) of the second element in the second pattern is greater than a content (at%) of the second element in the first pattern.

According to an aspect of the disclosure, a semiconductor device includes: a substrate including a first surface and a second surface opposing each other; a first semiconductor layer on the first surface of the substrate, the first semiconductor layer having a first conductivity type; a second semiconductor layer on the first semiconductor layer, the second semiconductor layer having a second conductivity type that is different from the first conductivity type; a third semiconductor layer on the second semiconductor layer, the third semiconductor layer having the first conductivity type and including silicon carbide (SiC); a gate electrode on the third semiconductor layer; a semiconductor pattern on the third semiconductor layer, the semiconductor pattern having the second conductivity type and including SiC; an anode electrode on the semiconductor pattern; and a cathode electrode on a lower surface of the first semiconductor layer, wherein the semiconductor pattern includes: a first pattern having a first energy band gap and including Si at a first content (at%); and a second pattern between the first pattern and the third semiconductor layer, the second pattern including Si at a second content (at%) smaller than the first content (at%).

According to an aspect of the disclosure, a method for manufacturing a semiconductor device may include the operations of sequentially forming a second semiconductor layer having a second conductivity type and a third semiconductor layer having a first conductivity type on a first semiconductor layer having the first conductivity type, forming a semiconductor pattern having the second conductivity type and including: a second pattern including a semiconductor material having a second energy band gap, and a first pattern including a semiconductor material having a first energy band gap smaller than the second energy band gap on the third semiconductor layer, patterning the semiconductor pattern to expose at least a portion of the third semiconductor layer, and forming a gate electrode on the third semiconductor layer, forming an anode electrode on the semiconductor pattern, and forming a cathode electrode on a lower surface of the first semiconductor layer.

The forming the semiconductor pattern may form the semiconductor pattern by using epitaxial growth using the third semiconductor layer as a seed.

The first semiconductor layer may include a material having a third energy band gap that is equal to or greater than the second energy band gap.

The first pattern and the second pattern include a first element and a second element, and a content (at%) of the first element in the second pattern may be less than a content (at%) of the first element in the first pattern.

The first semiconductor layer includes the first element and the second element, and the content (at%) of the first element in the second pattern may be greater than or equal to a content (at%) of the first element in the first semiconductor layer.

The first element may include Si, and the second element may include C.

The first semiconductor layer includes the first element and the second element, and the second pattern includes the first element, the second element, and a third element that is a semiconductor element different from the first element and the second element, and a content (at%) of the second element in the second pattern may be less than or equal to a content (at%) of the second element in the first semiconductor layer.

The first element may include Si, the second element may include C, and the third element may include Ge.

The second pattern includes the first element which is a semiconductor element, the second element, and the third element, and a content (at%) of the second element in the second pattern may be greater than the content (at%) of the second element in the first pattern.

### BRIEF DESCRIPTION OF THE DRAWINGS

The above and other aspects and features will be more apparent from the following description of one or more example embodiments taken in conjunction with the accompanying drawings, in which:

FIG. 1 is a cross-sectional view showing a semiconductor device according to one or more example embodiments;

FIG. 2 is a graph illustrating a semiconductor pattern of a semiconductor device and a content of a material constituting a third semiconductor layer according to one or more example embodiments;

FIGS. 3, 4, 5, 6, 7 and 8 are graphs illustrating the semiconductor pattern of a semiconductor device and a content of a material constituting a third semiconductor layer according to one or more example embodiments;

FIG. 9 is a cross-sectional view illustrating a semiconductor device according to one or more example embodiments;

FIGS. 10, 11 and 12 are graphs illustrating the semiconductor pattern of a semiconductor device and a content of a material constituting a third semiconductor layer according to one or more example embodiments illustrated in FIG. 9;

FIG. 13 is a cross-sectional view illustrating a semiconductor device according to one or more example embodiments; and

FIGS. 14, 15, 16 and 17 are intermediate process cross-sectional views showing a method for manufacturing a semiconductor device according to one or more example embodiments.

### DETAILED DESCRIPTION

Hereinafter, various example embodiments will be described in detail with reference to the attached drawings so that a person having ordinary skill in the art may easily implement the disclosure. The present disclosure may be embodied in many different forms and are not limited to the embodiments described herein.

In order to clearly explain example embodiments, parts irrelevant to the description may be omitted, and the same reference numerals are used for identical or similar components throughout the specification.

In addition, the size and the thickness of each component shown in the drawings are arbitrarily shown for convenience of explanation, so embodiments is not necessarily limited to what is shown in the drawings. To clearly represent the various layers and areas in the drawings, the thickness is enlarged and shown. And in the drawings, for convenience of explanation, the thickness of some layers and areas is exaggerated.

Also, when the description below says that a part, such as a layer, membrane, region, or plate, is “over” or “on” another part, this includes not only cases where the part is “directly over” the other part, but also cases where there are other parts in between. Conversely, when the description below says that a part is “directly above” another part, this may mean that there is no other part in between. Also, being “above” or “on” a reference part means being located above or below the reference part, and does not necessarily mean being located “above” or “on” opposite to a direction of gravity.

As used herein, expressions such as “at least one of,” when preceding a list of elements, modify the entire list of elements and do not modify the individual elements of the list. For example, the expression, "at least one of a, b, or c," should be understood as including only a, only b, only c, both a and b, both a and c, both b and c, or all of a, b, and c.

Additionally, throughout the description below, whenever a part is said to “include” a component, this does not mean that it excludes other components, but rather that the part may include other components, unless otherwise specifically stated.

Additionally, throughout the description below, when the description says “in plan”, this means when the target portion is viewed from above, and when the description says “in cross section”, this means when the target portion is viewed from the side in a cross-section cut vertically.

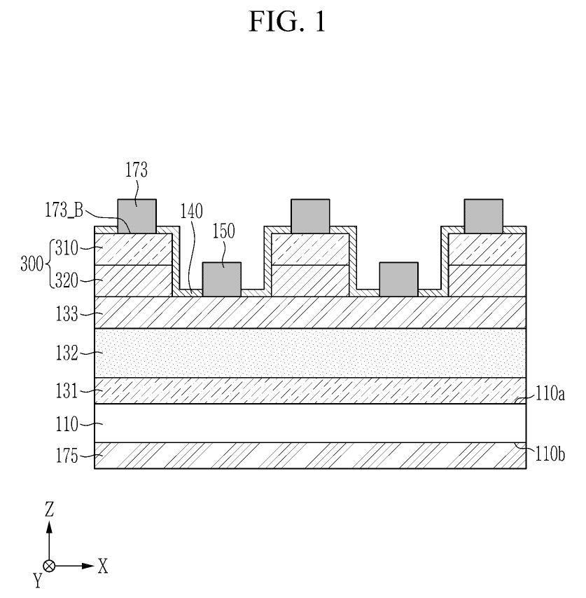

Hereinafter, referring to FIG. 1, a semiconductor device according to one or more example embodiments will be described.

FIG. 1 is a plan view showing a semiconductor device according to one or more example embodiments.

A semiconductor device according to one or more example embodiments may be a thyristor. For example, a semiconductor device according to one or more example embodiments may be a GTO thyristor (Gate Turn-Off thyristor) device having improved turn-off characteristics, but example embodiments are not limited thereto. A thyristor may have a structure in which a PNP BJT transistor (Bipolar Junction Transistor) and an NPN BJT transistor (Bipolar Junction Transistor) are combined with each other. In one or more example embodiments, the thyristor may be configured to handle high voltages and high currents by combining a PNP transistor and a NPN transistor through mutual current amplification, etc. For example, a thyristor may be used as a power device, but one or more example embodiments is not limited to this and use of a thyristor may be varied.

Referring to FIG. 1, a semiconductor device according to one or more example embodiments includes a substrate 110, a first semiconductor layer 131 positioned on a first surface 110a of the substrate 110, a second semiconductor layer 132 positioned on the first semiconductor layer 131, a third semiconductor layer 133 positioned on the second semiconductor layer 132, a gate electrode 150 positioned on the third semiconductor layer 133, a semiconductor pattern 300 positioned on the third semiconductor layer 133, an anode electrode 173 positioned on the semiconductor pattern 300, and a cathode electrode 175 positioned on the second surface 110b of the substrate 110.

The substrate 110 may be a semiconductor substrate including SiC. For example, the substrate 110 may be made of a 4H SiC substrate. In one or more example embodiments, the substrate 110 may be made of a 3C SiC substrate, a 6H SiC substrate, etc. The substrate 110 may be doped with first conductivity type impurities. For example, the first conductivity type impurity may be an n-type impurity. In other words, the substrate 110 may be doped as n-type. The substrate 110 may be heavily doped as n-type. The resistivity of the substrate 110 may be between about 0.005Ωcm and about 0.035Ωcm. The thickness of the substrate 110 may be from about 10 μm to about 700 μm. The material, doping type, doping concentration, resistivity, thickness, etc., of the substrate 110 are not limited to the aforementioned example embodiments and may be variously changed.

The substrate 110 may include a first surface 110a and a second surface 110b opposing each other. For example, the first surface 110a of the substrate 110 may refer to the upper surface of the substrate 110, and the second surface 110b of the substrate 110 may refer to the lower surface of the substrate 110.

The first semiconductor layer 131 may be positioned on the first surface 110a of the substrate 110, i.e., the upper surface of the substrate 110. The lower surface of the first semiconductor layer 131 may be in contact with the first surface 110a of the substrate 110. However, example embodiments are not limited thereto, and other layers may be additionally positioned between the substrate 110 and the first semiconductor layer 131. The first semiconductor layer 131 may be an epitaxial layer formed from the substrate 110 using an epitaxial growth method. The first semiconductor layer 131 may include SiC. For example, the first semiconductor layer 131 may include 4H SiC. The first semiconductor layer 131 may have a first conductivity type. The first conductivity type may be n-type. For example, the first semiconductor layer 131 may be doped as n-type. The first semiconductor layer 131 may be lightly doped as n-type. The doping concentration of the first semiconductor layer 131 may be lower than the doping concentration of the substrate 110. The doping concentration of the first semiconductor layer 131 may be between about 1*10¹⁵cm⁻³ and about 1*10¹⁷cm⁻³. The thickness of the first semiconductor layer 131 may be about 1 μm or more and about 13 μm or less.

The second semiconductor layer 132 may be positioned on the first semiconductor layer 131. The second semiconductor layer 132 may be positioned on top of the first semiconductor layer 131. The second semiconductor layer 132 may include SiC. For example, the second semiconductor layer 132 may include 4H SiC. The second semiconductor layer 132 may be an epitaxial layer formed from the first semiconductor layer 131 using an epitaxial growth method. The second semiconductor layer 132 may have a second conductivity type different from the first conductivity type. The second conductivity type may be p-type. For example, the second semiconductor layer 132 may be doped as p-type. The second semiconductor layer 132 may be lightly doped as p-type. The doping concentration of the second semiconductor layer 132 may be about 1*10¹⁷cm⁻³ or more and about 1*10¹⁹cm⁻³ or less. The material, doping type, doping concentration, etc. of the second semiconductor layer 132 are not limited to the aforementioned example embodiments and may be changed in various ways.

The third semiconductor layer 133 may be positioned on the second semiconductor layer 132. The third semiconductor layer 133 may be positioned on top of the second semiconductor layer 132. The third semiconductor layer 133 may include SiC. For example, the third semiconductor layer 133 may include 4H SiC. The third semiconductor layer 133 may have a first conductivity type. The first conductivity type may be n-type. For example, the third semiconductor layer 133 may be doped as n-type. The doping concentration of the third semiconductor layer 133 may be less than or equal to the doping concentration of the first semiconductor layer 131, but example embodiments are not limited thereto. The material, doping type, doping concentration, etc. of the third semiconductor layer 133 are not limited to the aforementioned example embodiments and may be changed in various ways.

The gate electrode 150 may be positioned on the third semiconductor layer 133. The gate electrode 150 may be positioned on the side surface of the semiconductor pattern 300, which will be described later. The gate electrode 150 may be spaced apart from the semiconductor pattern 300, which will be described later, in the first direction (X direction). The gate electrode 150 may not overlap with the semiconductor pattern 300 described later in the third direction (Z direction). Here, the third direction (Z direction) may mean a vertical direction perpendicular to the thickness direction of the substrate 110 and/or the first surface 110a of the substrate 110. The gate electrode 150 may include a conductive material. For example, the gate electrode 150 may include polysilicon doped with impurities. As another example, the gate electrode 150 may include a metal, a metal alloy, a conductive metal nitride, a metal silicide, a doped semiconductor material, a conductive metal oxide, a conductive metal nitride, or a combination thereof. The gate electrode 150 may be formed of a single layer or multiple layers.

The semiconductor pattern 300 may be positioned on the third semiconductor layer 133. The semiconductor pattern 300 may be positioned between the third semiconductor layer 133 and the anode electrode 173, which will be described later. The semiconductor pattern 300 may be spaced apart from the gate electrode 150 in the first direction (X direction). The semiconductor pattern 300 may not overlap with the gate electrode 150 in the third direction (Z direction).

A semiconductor device according to one or more example embodiments may include a plurality of semiconductor patterns 300 arranged spaced apart in the first direction (X direction) on a third semiconductor layer 133. The plurality of semiconductor patterns 300 may be positioned directly on the third semiconductor layer 133. The gate electrode 150 may be positioned between the plurality of semiconductor patterns 300. The widths of each of the plurality of semiconductor patterns 300 in the first direction (X direction) may be substantially the same, but example embodiments are not limited thereto. The lengths of each of the plurality of semiconductor patterns 300 in the third direction (Z direction) may be substantially the same, but example embodiments are not limited thereto.

The semiconductor pattern 300 may include a semiconductor material. The work function of the semiconductor pattern 300 may be greater than or equal to the work function of the anode electrode 173. The semiconductor pattern 300 may include the same material as the first semiconductor layer 131, the second semiconductor layer 132, and the third semiconductor layer 133. For example, the semiconductor pattern 300 may include a first element that is a semiconductor element and a second element that is different from the first element. Here, the first element may include Si, and the second element may include C. For example, the semiconductor pattern 300 may be SiₓC₁₋ₓ (0<x<1). For example, the first semiconductor layer 131, the second semiconductor layer 132, the third semiconductor layer 133, and the semiconductor pattern 300 may all include SiₓC₁₋ₓ (0<x<1). The semiconductor pattern 300 may be an epitaxial layer formed from the third semiconductor layer 133 using an epitaxial growth method. For example, the semiconductor pattern 300 may be composed of a superlattice layer. When the semiconductor pattern 300 is composed of a superlattice layer, the difference in lattice constant and thermal expansion coefficient with the surrounding material layers may be alleviated. The semiconductor pattern 300 may have a second conductivity type. The second conductivity type may be p-type. The semiconductor pattern 300 may be doped with second conductivity type impurities. The doping concentration of the second conductivity type impurity of the semiconductor pattern 300 may be greater than or equal to the doping concentration of the second conductivity type impurity of the second semiconductor layer 132, but example embodiments are not limited thereto. In one or more example embodiments, the doping concentration of the second conductivity type impurity of the semiconductor pattern 300 may be less than the doping concentration of the second conductivity type impurity of the second semiconductor layer 132.

As another example, the first semiconductor layer 131, the second semiconductor layer 132, the third semiconductor layer 133, and the semiconductor pattern 300 may all include GaN. In this case, the first element may be Ga and the second element may be N.

The semiconductor pattern 300 may include multiple layers having different energy band gaps. For example, the semiconductor pattern 300 may include a first pattern 310 including a semiconductor material having a first energy band gap and a second pattern 320 including a semiconductor material having a second energy band gap larger than the first energy band gap.

The first pattern 310 may be positioned on the third semiconductor layer 133. The first pattern 310 may be positioned on the lower surface 173_B of the anode electrode 173, which will be described later. The first pattern 310 may be positioned between the third semiconductor layer 133 and the anode electrode 173, which will be described later. The first pattern 310 may contact the lower surface 173_B of the anode electrode 173. The first pattern 310 may not overlap with the gate electrode 150 in the third direction (Z direction).

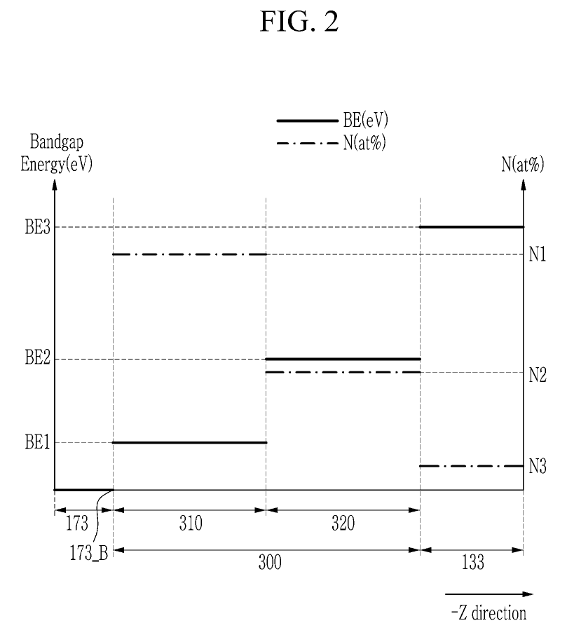

The first pattern 310 may include a semiconductor material. The work function of the first pattern 310 may be greater than or equal to the work function of the anode electrode 173. The first pattern 310 may include the same material as the first semiconductor layer 131, the second semiconductor layer 132, and the third semiconductor layer 133. For example, the first pattern 310 may include a first element and a second element. Here, the first element may be Si and the second element may be C, but example embodiments are not limited thereto. For example, the first pattern 310 could be SiₓC₁₋ₓ (0<x<1). In this case, the semiconductor material constituting the first pattern 310 may have the first energy band gap (see BE1 of FIG. 2). A description of this will be given later, referring to FIG. 2.

The second pattern 320 may be positioned between the first pattern 310 and the third semiconductor layer 133. The second pattern 320 may be positioned on the lower surface of the first pattern 310. The second pattern 320 may be in contact with the lower surface of the first pattern 310, but example embodiments are not limited thereto. The second pattern 320 may not overlap with the gate electrode 150 in the third direction (Z direction).

The second pattern 320 may include a semiconductor material. The second pattern 320 may include the same material as the first pattern 310. The second pattern 320 may include the same material as the first semiconductor layer 131, the second semiconductor layer 132, and the third semiconductor layer 133. For example, the second pattern 320 may include a first element and a second element. Here, the first element may be Si and the second element may be C, but example embodiments are not limited thereto. For example, the second pattern 320 could be SiₓC₁₋ₓ (0<x<1). In this case, the semiconductor material constituting the second pattern 320 may have a second energy band gap (see BE2 of FIG. 2). A description of this will be given later, referring to FIG. 2.

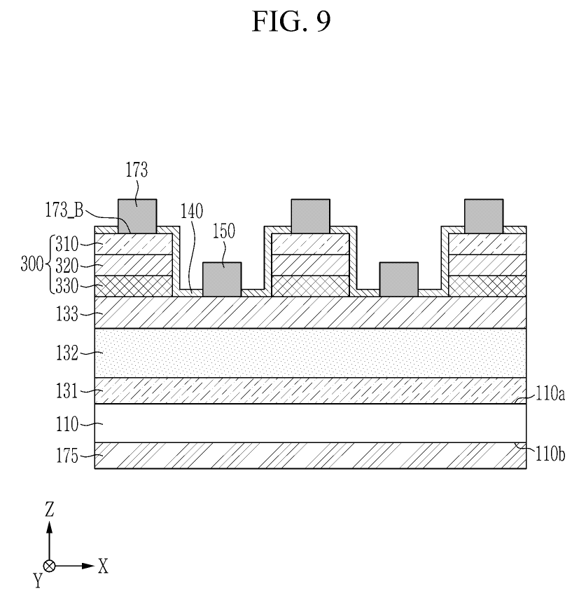

In FIG. 1, the semiconductor pattern 300 is illustrated as including two patterns 310 and 320, but the number of patterns 310 and 320 is not limited thereto. For example, as in one or more example embodiments of FIGS. 9, 10, 11 and 12, the semiconductor pattern 300 may include three patterns 310, 320, and 330. As another example, the semiconductor pattern 300 may include four or more patterns. A description of this will be given later with reference to FIGS. 9, 10, 11 and 12.

A semiconductor device according to one or more example embodiments may further include an interlayer insulating layer 140 positioned on the semiconductor pattern 300 and the third semiconductor layer 133.

The interlayer insulating layer 140 may be positioned on the upper surface of the semiconductor pattern 300, the side surface of the semiconductor pattern 300, and the upper surface of the third semiconductor layer 133. The interlayer insulating layer 140 may be conformally positioned on the upper surface of the semiconductor pattern 300, the side surface of the semiconductor pattern 300, and the upper surface of the third semiconductor layer 133. The thickness of the interlayer insulating layer 140 may be almost constant. The interlayer insulating layer 140 may be in contact with the semiconductor pattern 300 and the third semiconductor layer 133, but example embodiments are not limited thereto. In one or more example embodiments, the gate electrode 150 may penetrate the interlayer insulating layer 140 and contact the third semiconductor layer 133. In one or more example embodiments, the anode electrode 173, which will be described later, may penetrate the interlayer insulating layer 140 and come into contact with the semiconductor pattern 300. The interlayer insulating layer 140 may include an insulating material. For example, the interlayer insulating layer 140 may include SiO₂. However, example embodiments are not limited thereto, and the material of the interlayer insulating layer 140 may be changed in various ways. As another example, the interlayer insulating layer 140 may include SiN, SiON, SiC, SiCN or a combination thereof. The interlayer insulating layer 140 may be composed of a single layer or multiple layers.

The anode electrode 173 may be positioned on the semiconductor pattern 300. The anode electrode 173 may be electrically connected to the semiconductor pattern 300 through the interlayer insulating layer 140. The anode electrode 173 may not overlap with the gate electrode 150 in the third direction (Z direction).

A semiconductor device according to one or more example embodiments may include a plurality of anode electrodes 173 arranged spaced apart in the first direction (X direction) on the semiconductor pattern 300. The plurality of anode electrodes 173 may be positioned directly on the semiconductor pattern 300. The widths of each of the plurality of anode electrodes 173 in the first direction (X direction) may be substantially the same, but example embodiments are not limited thereto. The lengths of each of the plurality of anode electrodes 173 in the third direction (Z direction) may be substantially equal to each other, but example embodiments are not limited thereto.

The anode electrode 173 may include a conductive material. The anode electrode 173 may comprise the same material as the gate electrode 150, but example embodiments are not limited thereto. The anode electrode 173 may comprise a different material than the gate electrode 150. For example, the anode electrode 173 may include a metal, a metal alloy, a conductive metal nitride, a metal silicide, a doped semiconductor material, a conductive metal oxide, or a conductive metal nitride. For example, the anode electrode 173 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbide nitride (TiAlC-N), titanium aluminum carbide (TiAlC), titanium carbide (TiC), tantalum carbide nitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof. The anode electrode 173 may be composed of a single layer or multiple layers.

The cathode electrode 175 may be positioned on the second surface 110b of the substrate 110, i.e., the lower surface of the substrate 110. The upper surface of the cathode electrode 175 may be in contact with the lower surface of the substrate 110. The cathode electrode 175 may be in ohmic contact with the substrate 110. The region in contact with the cathode electrode 175 within the substrate 110 may be doped at a relatively high concentration compared to other regions. However, example embodiments are not limited thereto, and additional layers may be positioned between the cathode electrode 175 and the substrate 110. For example, a silicide layer may be positioned between the cathode electrode 175 and the substrate 110. The silicide layer may include a metal silicide material. The metal silicide layer enables smooth electrical connection between the cathode electrode 175 and the substrate 110.

The cathode electrode 175 may include a conductive material. For example, the cathode electrode 175 may include a metal, a metal alloy, a conductive metal nitride, a metal silicide, a doped semiconductor material, a conductive metal oxide, or a conductive metal nitride. The cathode electrode 175 may be made of the same material as the anode electrode 173 and/or the gate electrode 150, or may be made of a different material. The cathode electrode 175 may be composed of a single layer or multiple layers.

A semiconductor device according to one or more example embodiments may be a thyristor. For example, a semiconductor device according to one or more example embodiments may be a GTO thyristor (Gate Turn-Off thyristor) device having improved turn-off characteristics, but example embodiments are not limited thereto. Specifically, the second semiconductor layer 132, the third semiconductor layer 133, and the semiconductor pattern 300 may form a PNP transistor. The third semiconductor layer 133 may be the base region of a PNP transistor. The first semiconductor layer 131, the second semiconductor layer 132, and the third semiconductor layer 133 may form an NPN transistor. The second semiconductor layer 132 may be the base region of the second NPN transistor. The gate electrode 150 may be electrically connected to the third semiconductor layer 133.

In an example embodiment, the thyristor may be configured to handle high voltages and high currents by combining a PNP transistor and an NPN transistor through mutual current amplification, etc. For example, a thyristor may be used as a power device, but one or more example embodiments is not limited to this and use of the thyristor may be varied.

Hereinafter, with further reference to FIG. 2, patterns 310 and 320 of a semiconductor device according to one or more example embodiments will be described in detail.

FIG. 2 is a graph illustrating a semiconductor pattern of a semiconductor device and a content of a material constituting a third semiconductor layer according to one or more example embodiments. FIG. 2 shows the energy band gap and a content of the first element in the anode electrode 173, the first pattern 310, the second pattern 320, and the third semiconductor layer 133 in the direction (-Z direction) from the anode electrode 173 toward the first surface 110a of the substrate 110. Here, ‘content’ may mean atomic percent (at%).

As described above, the third semiconductor layer 133, the first pattern 310, and the second pattern 320 of the semiconductor device according to one or more example embodiments may include the same material. For example, the third semiconductor layer 133, the first pattern 310, and the second pattern 320 may include a first element that is a semiconductor element and a second element that is different from the first element. Here, the first element may be Si and the second element may be C, but example embodiments are not limited thereto. The third semiconductor layer 133, the first pattern 310, and the second pattern 320 may be SiₓC₁₋ₓ (0<x<1).

Referring further to FIG. 2, the first pattern 310, the second pattern 320, and the third semiconductor layer 133 may include a material having a predetermined energy band gap. In this case, the energy band gap may be determined according to the contents (at%) of the first element and the second element of the semiconductor material constituting the first pattern 310, the second pattern 320, and the third semiconductor layer 133. Specifically, as a content (at%) of the first element, which is a semiconductor element, increases, the energy band gap tends to narrow. That is, as a content (at%) of the second element increases, the energy band gap tends to widen. For example, the first pattern 310 of a semiconductor device according to one or more example embodiments may include a material having a first energy band gap BE1, the second pattern 320 may include a material having a second energy band gap BE2, and the third semiconductor layer 133 may include a material having a third energy band gap BE3. The energy band gap of the anode electrode 173 may be approximately ‘0’.

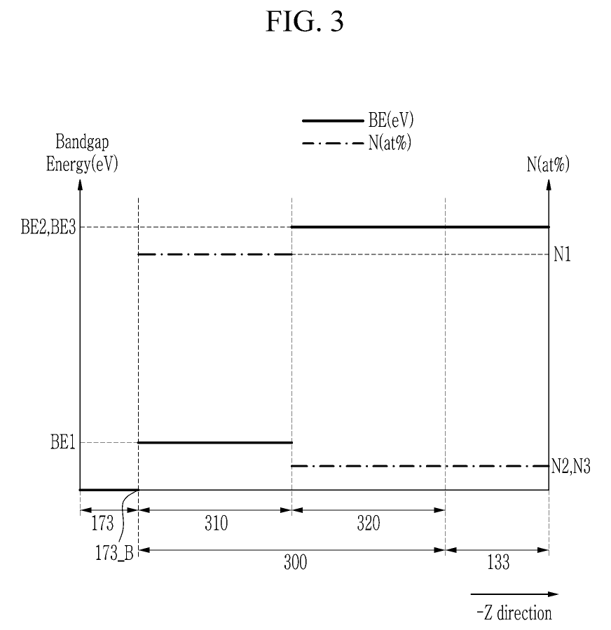

The semiconductor pattern 300 may include portions having different energy band gaps. For example, the energy band gap of the upper side of the semiconductor pattern 300 may be smaller than the energy band gap of the lower side of the semiconductor pattern 300. For example, the energy band gap of the semiconductor material constituting the semiconductor pattern 300 may increase in a step-like manner in the direction (-Z direction) from the lower surface 173_B of the anode electrode 173 toward the first surface 110a of the substrate 110. However, example embodiments are not limited thereto, and the energy band gap of the semiconductor pattern 300 may be variously changed within a range that increases in the direction (-Z direction) from the lower surface 173_B of the anode electrode 173 toward the first surface 110a of the substrate 110. A detailed description of this will be given later in FIGS. 3, 4, 5, 6 and 7.

Specifically, the first energy band gap BE1 of the first pattern 310 may be smaller than the second energy band gap BE2 of the second pattern 320. The first energy band gap BE1 and the second energy band gap BE2 may have substantially constant sizes, but example embodiments are not limited thereto. Therefore, the energy band gap of the upper part of the semiconductor pattern 300 may be smaller than the energy band gap of the lower part of the semiconductor pattern 300. The conductivity of the first pattern 310 may be greater than the conductivity of the second pattern 320. The work function of the first pattern 310 may be smaller than the work function of the second pattern 320.

According to one or more example embodiments, a content N1 of the first element in the first pattern 310 may be different from a content N2 of the first element in the second pattern 320. For example, because the energy band gap tends to become smaller as the content of the first element, which is a semiconductor element, increases, the content N1 of the first element in the first pattern 310 may be greater than the content N2 of the first element in the second pattern 320. A content of the second element in the first pattern 310 may be less than a content of the second element in the second pattern 320. Here, the first element may be Si and the second element may be C, but example embodiments are not limited thereto.

Additionally, the second energy band gap BE2 of the second pattern 320 may be smaller than the third energy band gap BE3 of the third semiconductor layer 133. The second energy band gap BE2 and the third energy band gap BE3 may have substantially constant sizes, but example embodiments are not limited thereto. The conductivity of the second pattern 320 may be greater than the conductivity of the third semiconductor layer 133.

According to one or more example embodiments, the content N2 of the first element in the second pattern 320 may be different from a content N3 of the first element in the third semiconductor layer 133. For example, because the energy band gap tends to become smaller as the content of the first element, which is a semiconductor element, increases, the content N2 of the first element in the second pattern 320 may be greater than the content N3 of the first element in the third semiconductor layer 133, but example embodiments are not limited thereto. The content of the second element in the second pattern 320 may be less than a content of the second element in the third semiconductor layer 133. Here, the first element may be Si and the second element may be C, but example embodiments are not limited thereto.

The semiconductor pattern 300 of a semiconductor device according to one or more example embodiments may include a portion having a smaller energy band gap closer to the anode electrode 173. For example, the first energy band gap BE1 of the first pattern 310 in contact with the lower surface 173_B of the anode electrode 173 may be smaller than the second energy band gap BE2 of the second pattern 320. A material forming the semiconductor pattern 300 of a semiconductor device according to one or more example embodiments has a tendency for the Fermi level of the material to rise as the energy band gap becomes smaller, and a tendency for the work function of the material to decrease. Accordingly, the work function of the first pattern 310 including a material having a relatively small energy band gap may be reduced, and thus the contact characteristics between the anode electrode 173 and the first pattern 310 may be improved. Additionally, because the first pattern 310 has a small energy band gap, the activation energy may decrease, thereby increasing the conductivity of the semiconductor pattern 300. Here, activation energy may mean the amount of energy required for a hole to be conducted into the valence band. Accordingly, the reliability of a semiconductor device according to one or more example embodiments may be improved.

Additionally, when holes move from the semiconductor pattern 300 to the third semiconductor layer 133, the mobility of the holes may be determined by the size of the energy barrier between the material layers. For example, the lower the energy barrier of a material layer, the lower the required activation energy, and the easier it is for holes to move into the material layer. Here, activation energy may mean the amount of energy required for a hole to be conducted into the valence band.

A semiconductor device according to one or more example embodiments may include a first pattern 310 having a first energy band gap BE1 smaller than a third energy band gap BE3 of the third semiconductor layer 133. Because the first pattern 310 includes a material having a small energy band gap, the hole density within the first pattern 310 may increase and the holes may move easily.

Additionally, the semiconductor pattern 300 of the semiconductor device according to one or more example embodiments may include the second pattern 320 having a second energy band gap BE2 that is larger than a first energy band gap BE1 of the first pattern 310 and smaller than a third energy band gap BE3 of the third semiconductor layer 133. Accordingly, a relatively low-height energy barrier is formed between the first pattern 310 and the second pattern 320 and between the second pattern 320 and the third semiconductor layer 133, allowing holes to move easily. Accordingly, the reliability of a semiconductor device according to one or more example embodiments may be improved.

Additionally, the content N2 of the first element in the second pattern 320 may be less than the content N1 of the first element in the first pattern 310, and may be greater than the content N3 of the first element in the third semiconductor layer 133. As the content of the first element sequentially increases in the third semiconductor layer 133, the second pattern 320, and the first pattern 310, the occurrence of defects due to the difference in lattice constants at the interface between materials of different contents (at%) may be prevented. Accordingly, the reliability of a semiconductor device according to one or more example embodiments may be improved.

Hereinafter, semiconductor patterns of semiconductor devices according to one or more example embodiments will be described with reference to FIGS. 3, 4, 5, 6, 7 and 8.

FIGS. 3, 4, 5, 6, 7 and 8 are graphs illustrating the semiconductor pattern of a semiconductor device and a content of a material constituting a third semiconductor layer according to one or more example embodiments.

FIGS. 3, 4, 5, 6, 7 and 8 illustrate various modifications of a semiconductor device according to one or more example embodiments illustrated in FIGS. 1 and 2. One or more example embodiments illustrated in FIGS. 3, 4, 5, 6, 7 and 8 are substantially similar to one or more example embodiments illustrated in FIGS. 1 and 2, so a duplicate description thereof will be omitted and the differences will be mainly described. Additionally, the same drawing symbols are used for the same components as in the previous example embodiment.

Referring to FIGS. 1 and 3, a second energy band gap BE2 of the second pattern 320 of a semiconductor device according to one or more example embodiments may be substantially equal to a third energy band gap BE3 of the third semiconductor layer 133. The second energy band gap BE2 and the third energy band gap BE3 may have substantially constant sizes, but example embodiments are not limited thereto. The conductivity of the second pattern 320 may be substantially the same as the conductivity of the third semiconductor layer 133, but example embodiments are not limited thereto.

According to one or more example embodiments, the content N2 of the first element in the second pattern 320 may be substantially equal to the content N3 of the first element in the third semiconductor layer 133. The content of the second element in the second pattern 320 may be substantially the same as the content of the second element in the third semiconductor layer 133. Here, the first element may be Si and the second element may be C, but example embodiments are not limited thereto.

In the example embodiment of FIG. 3, the second energy band gap BE2 of the second pattern 320 may be substantially the same as the third energy band gap BE3 of the third semiconductor layer 133. In this case, the second pattern 320 has a p-type and the third semiconductor layer 133 has an n-type, so an energy barrier exists between the second pattern 320 and the third semiconductor layer 133. Therefore, compared to the case where the second pattern 320 is not present, a relatively low-sized energy barrier is formed between the first pattern 310 and the second pattern 320 and between the second pattern 320 and the third semiconductor layer 133, allowing holes to move easily. Accordingly, the reliability of a semiconductor device according to one or more example embodiments may be improved.

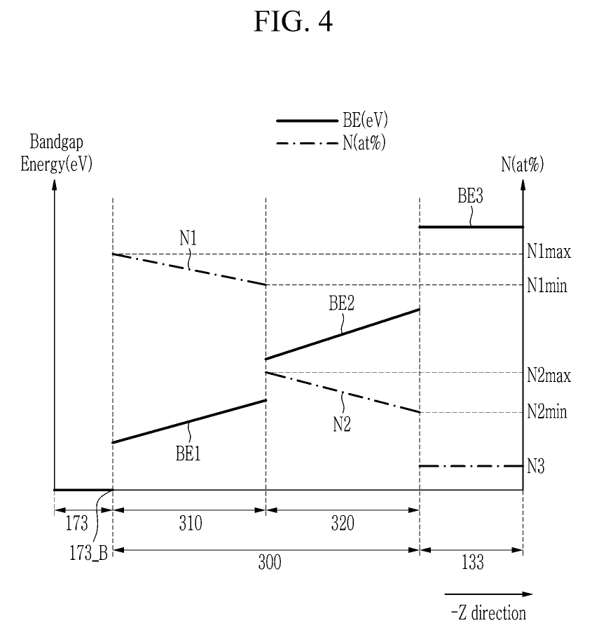

Referring to FIG. 1 and FIGS. 4, 5, 6 and 7, the semiconductor pattern 300 of the semiconductor device according to one or more example embodiments may include a portion in which the energy band gap increases as it moves away from the lower surface 173_B of the anode electrode 173. For example, the energy band gap of the first pattern 310 and the second pattern 320 may increase as they move away from the lower surface 173_B of the anode electrode 173.

According to one or more example embodiments, the content N1 of the first element in the first pattern 310 and the content N2 of the first element in the second pattern 320 may vary in the direction (-Z direction) from the lower surface 173_B of the anode electrode 173 toward the first surface 110a of the substrate 110. For example, the content N1 of the first element in the first pattern 310 may decrease in the direction (-Z direction) from the lower surface 173_B of the anode electrode 173 toward the first surface 110a of the substrate 110. The content N2 of the first element in the second pattern 320 may decrease in the direction (-Z direction) from the lower surface 173_B of the anode electrode 173 toward the first surface 110a of the substrate 110. That is, the content N2 of the first element in the second pattern 320 may decrease as it moves away from the first pattern 310.

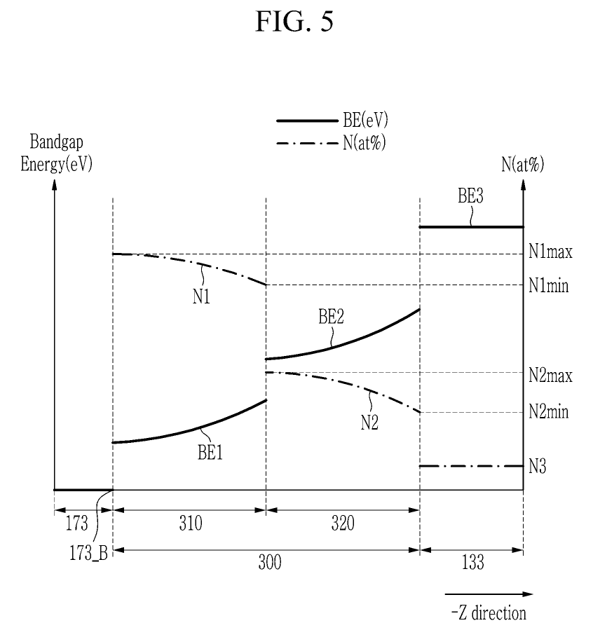

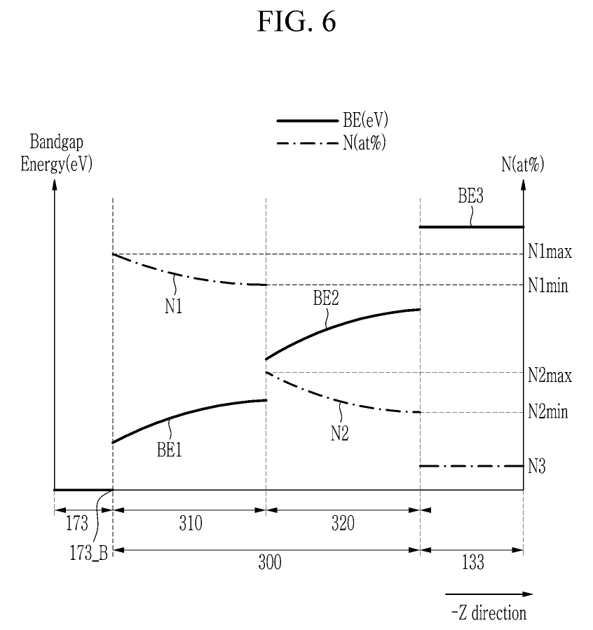

In this case, the change rate of the content N1 of the first element in the first pattern 310 and the change rate of the content of the second element in the second pattern 320 may be changed in various ways. For example, as illustrated in FIG. 4, the change rate of the content N1 of the first element in the first pattern 310 and the change rate of the content of the second element in the second pattern 320 may be constant. As another example, as illustrated in FIG. 5, the rate of change in the content N1 of the first element in the first pattern 310 and the rate of change in the content of the second element in the second pattern 320 may increase. As another example, as illustrated in FIG. 6, the rate of change in the content N1 of the first element in the first pattern 310 and the rate of change in the content of the second element in the second pattern 320 may decrease. Here, the change rate of the content N1 of the first element in the first pattern 310 and the change rate of the content of the second element in the second pattern 320 may mean the change amount of the content per unit distance in the direction (-Z direction) from the lower surface 173_B of the anode electrode 173 toward the first surface 110a of the substrate 110.

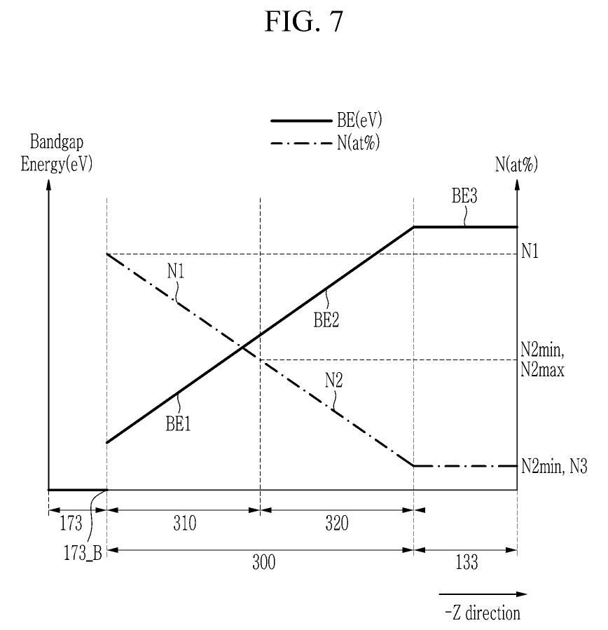

According to one or more example embodiments, the content N1 of the first element in the first pattern 310 may have a maximum value N1max near the lower surface 173_B of the anode electrode 173, and may have a minimum value N1min in a portion adjacent to the second pattern 320. Additionally, the content N2 of the first element in the second pattern 320 may have a maximum value N2max in a portion adjacent to the first pattern 310, and a minimum value N2min in a portion adjacent to the third semiconductor layer 133. For example, as illustrated in FIGS. 4, 5 and 6, the minimum value N1min of the content N1 of the first element in the first pattern 310 may be greater than the maximum value N2max of the content N2 of the first element in the second pattern 320. Additionally, the minimum value N2min of the content N2 of the first element in the second pattern 320 may be greater than the content N3 of the first element in the third semiconductor layer 133. However, example embodiments are not limited thereto, and as another example, as illustrated in FIG. 7, the minimum value N1min of the content N1 of the first element in the first pattern 310 may be substantially equal to the maximum value N2max of the content N2 of the first element in the second pattern 320. Additionally, the minimum value N2min of the content N2 of the first element in the second pattern 320 may be substantially equal to the content N3 of the first element in the third semiconductor layer 133.

Accordingly, the first energy band gap BE1 of the first pattern 310 may gradually increase in the direction (-Z direction) from the lower surface 173_B of the anode electrode 173 toward the first surface 110a of the substrate 110. The second energy band gap BE2 of the second pattern 320 may gradually increase in the direction (-Z direction) from the lower surface 173_B of the anode electrode 173 toward the first surface 110a of the substrate 110. Accordingly, the semiconductor device according to one or more example embodiments of FIGS. 4, 5, 6 and 7 may continuously form an energy barrier of relatively very low height, and thus the reliability of the semiconductor device according to one or more example embodiments may be improved.

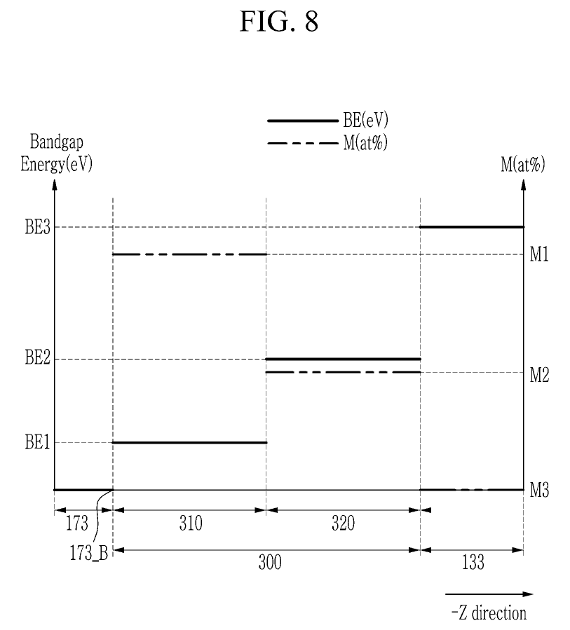

Referring to FIGS. 1 and 8, the first pattern 310 and the second pattern 320 of the semiconductor device according to one or more example embodiments may further include a third element that is a semiconductor element different from the first element and the second element. Here, the first element may be Si, the second element may be C, and the third element may be Ge. For example, the first pattern 310 and the second pattern 320 may be SiₓGe_{y}C_{1-x-y} (0<x<1, 0<y<1).

A content M1 of the third element in the first pattern 310 may be greater than a content M2 of the third element in the second pattern 320. In this case, a content of the first element in the first pattern 310 may be substantially the same as the content of the second element in the first pattern 310, but example embodiments are not limited thereto. Additionally, a content of the first element in the second pattern 320 may be substantially the same as the content of the second element in the second pattern 320, but example embodiments are not limited thereto.

According to one or more example embodiments, the content of the second element in the first pattern 310 may be less than the content of the second element in the second pattern 320. That is, the sum of the content of the first element in the first pattern 310 and the content M1 of the third element may be greater than the sum of the content of the first element in the second pattern 320 and the content M2 of the third element. In this range, the first energy band gap BE1 of the first pattern 310 may be smaller than the second energy band gap BE2 of the second pattern 320. For example, the content of the second element in the first pattern 310 may be less than the content of the second element in the second pattern 320, and the content of the first element in the first pattern 310 may be less than or equal to the content of the first element in the second pattern 320. In this case, the content M1 of the third element in the first pattern 310 may be greater than the content M2 of the third element in the second pattern 320, and the first energy band gap BE1 of the first pattern 310 may be smaller than the second energy band gap BE2 of the second pattern 320.

As another example, the content of the second element in the first pattern 310 may be substantially identical to the content of the second element in the second pattern 320. In this case, the content M1 of the third element in the first pattern 310 may be greater than the content M2 of the third element in the second pattern 320. In this range, the first energy band gap BE1 of the first pattern 310 may be smaller than the second energy band gap BE2 of the second pattern 320.

The content of the second element in the second pattern 320 may be less than or equal to the content of the second element in the third semiconductor layer 133. Accordingly, the second energy band gap BE2 of the second pattern 320 may be smaller than the third energy band gap BE3 of the third semiconductor layer 133.

In one or more example embodiments, the third semiconductor layer 133 may not include a third element. That is, a content M3 of the third element in the third semiconductor layer 133 may be approximately 0. However, example embodiments are not limited thereto, and the third semiconductor layer 133 may further include a third element. In this case, the content M3 of the third element in the third semiconductor layer 133 may be less than or equal to the content of the second element in the second pattern 320.

In one or more example embodiments, when the first pattern 310 and the second pattern 320 are composed of SiₓGe_{y}C_{1-x-y} (0<x<1, 0<y<1), the contents (at%) of the first element, the second element, and the third element of each of the first pattern 310 and the second pattern 320 may be variously changed within a range in which the first energy band gap BE1 of the first pattern 310 is smaller than the second energy band gap BE2 of the second pattern 320.

In one or more example embodiments of FIG. 8, the first element, the second element, and the third element constituting the first pattern 310, the second pattern 320, and the third semiconductor layer 133 may be variously changed. For example, the first element may include the semiconductor element Ga, the second element may include N, and the third element may include In. That is, the third semiconductor layer 133 may include GaN, and the first pattern 310 and the second pattern 320 may include InGaN. For example, the first pattern 310 and the second pattern 320 may be In_{z}Ga_{1-z}N (0<z<1). Even in this case, the first energy band gap BE1 of the first pattern 310 may be smaller than the second energy band gap BE2 of the second pattern 320, and the second energy band gap BE2 of the second pattern 320 may be smaller than or equal to the third energy band gap BE3 of the third semiconductor layer 133. For example, the In content (at%) in the first pattern 310 may be greater than the In content (at%) in the second pattern 320. The N content (at%) in the first pattern 310 may be substantially the same as the N content (at%) in the second pattern 320. The sum of the In content (at%) and the Ga content (at%) in the first pattern 310 may be substantially equal to the sum of the In content (at%) and the Ga content (at%) in the second pattern 320, but example embodiments are not limited thereto.

Hereinafter, referring to FIGS. 9, 10, 11 and 12, a semiconductor pattern of a semiconductor device according to one or more example embodiments will be described.

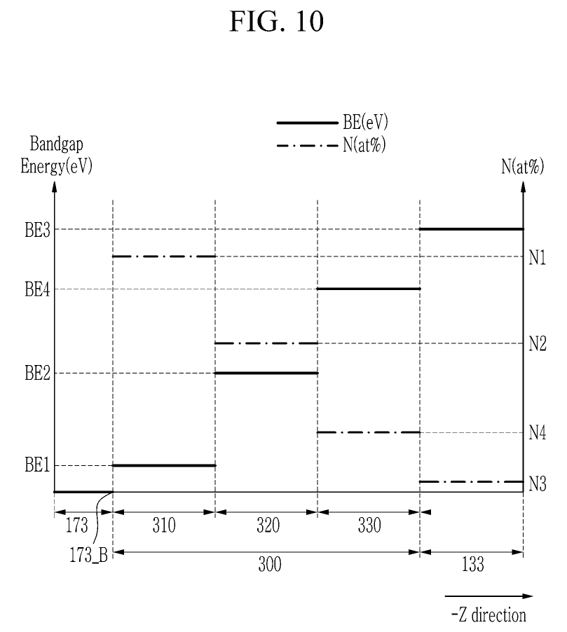

FIG. 9 is a cross-sectional view illustrating a semiconductor device according to one or more example embodiments. FIGS. 10, 11 and 12 are graphs illustrating the semiconductor pattern of a semiconductor device and the content of a material constituting a third semiconductor layer according to one or more example embodiments illustrated in FIG. 9.

FIGS. 9, 10, 11 and 12 illustrate various modifications of a semiconductor device according to one or more example embodiments illustrated in FIGS. 1, 2, 3, 4, 5, 6, 7 and 8. One or more example embodiments illustrated in FIGS. 9, 10, 11 and 12 are substantially similar to one or more example embodiments illustrated in FIGS. 1, 2, 3, 4, 5, 6, 7 and 8, so a duplicate description thereof will be omitted and the differences will be mainly explained. Additionally, the same drawing symbols are used for the same components as in the previous one or more example embodiments.

Referring to FIG. 9, the semiconductor pattern 300 of the semiconductor device according to one or more example embodiments may further include a third pattern 330 positioned between the second pattern 320 and the third semiconductor layer 133.

The third pattern 330 may be positioned on the third semiconductor layer 133. The third pattern 330 may be positioned on the lower surface of the second pattern 320. The third pattern 330 may be in contact with the third semiconductor layer 133, but example embodiments are not limited thereto. The third pattern 330 may overlap the anode electrode 173 in the third direction (Z direction). The third pattern 330 may be spaced apart from the anode electrode 173 in the third direction (Z direction).

The third pattern 330 may include a semiconductor material. The third pattern 330 may include the same material as the first pattern 310 and the second pattern 320. For example, the third pattern 330 may include a first element and a second element. Here, the first element may be Si and the second element may be C, but example embodiments are not limited thereto. For example, the first pattern 310, the second pattern 320, and the third pattern 330 may be SiₓC₁₋ₓ (0<x<1).

Referring to FIG. 10, the fourth energy band gap BE4 of the third pattern 330 may be larger than the second energy band gap BE2 of the second pattern 320. The conductivity of the third pattern 330 may be less than the conductivity of the second pattern 320. A content N4 of the first element in the third pattern 330 may be different from the content N2 of the first element in the second pattern 320. For example, because the energy band gap tends to narrow as the content of the first element, which is a semiconductor element, increases, the content N4 of the first element in the third pattern 330 may be smaller than the content N2 of the first element in the second pattern 320. The content of the second element in the third pattern 330 may be greater than the content of the second element in the second pattern 320.

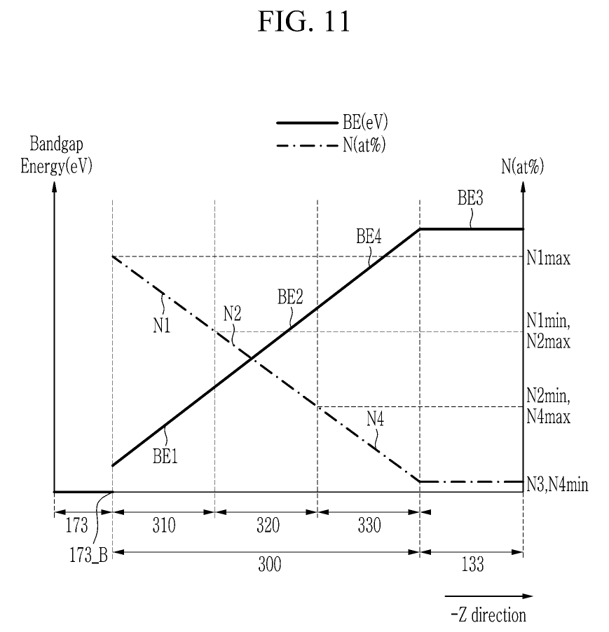

Referring to FIG. 11, the maximum value N4max of the content N4 of the first element in the third pattern 330 may be substantially equal to the minimum value N2min of the content N2 of the first element in the second pattern 320. Additionally, the minimum value N4min of the content N4 of the first element in the third pattern 330 may be substantially equal to the content N3 of the first element in the third semiconductor layer 133.

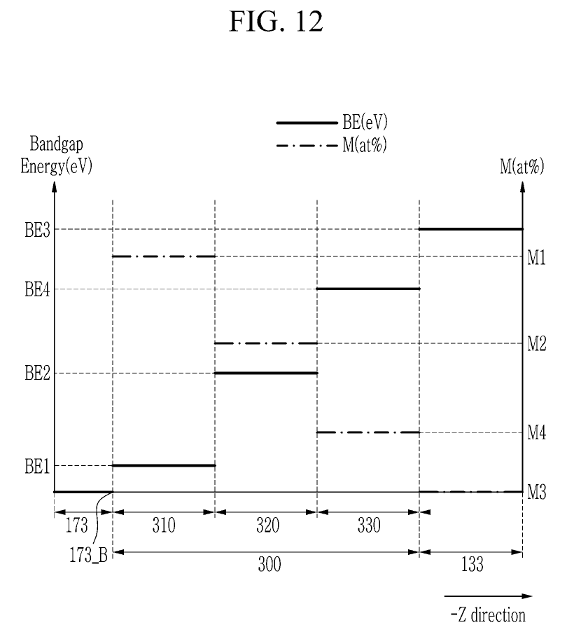

Referring to FIG. 12, the first pattern 310, the second pattern 320, and the third pattern 330 may further include a third element that is a semiconductor element different from the first element and the second element. Here, the first element may be Si, the second element may be C, and the third element may be Ge. For example, the first pattern 310, the second pattern 320, and the third pattern 330 may be SiₓGe_{y}C_{1-x-y} (0<x<1, 0<y<1).

A content M4 of the third element in the third pattern 330 may be less than the content M2 of the third element in the second pattern 320. In this case, the content of the first element in the third pattern 330 may be substantially the same as the content of the second element in the third pattern 330, but example embodiments are not limited thereto.

According to one or more example embodiments, the content of the second element in the third pattern 330 may be greater than or equal to the content of the second element in the second pattern 320. That is, the sum of the content of the first element in the third pattern 330 and the content M4 of the third element may be less than or equal to the sum of the content of the first element in the second pattern 320 and the content M2 of the third element. In this range, the fourth energy band gap BE4 of the third pattern 330 may be larger than the second energy band gap BE2 of the second pattern 320. The content of the second element in the third pattern 330 may be less than or equal to the content of the second element in the third semiconductor layer 133.

In one or more example embodiments, when the first pattern 310, the second pattern 320, and the third pattern 330 are composed of SiₓGe_{y}C_{1-x-y} (0<x<1, 0<y<1), the contents (at%) of the first element, the second element, and the third element of each of the first pattern 310, the second pattern 320, and the third pattern 330 may be variously changed within a range in which the first energy band gap BE1 of the first pattern 310 is smaller than the second energy band gap BE2 of the second pattern 320, and the second energy band gap BE2 of the second pattern 320 is smaller than the fourth energy band gap BE4 of the third pattern 330.

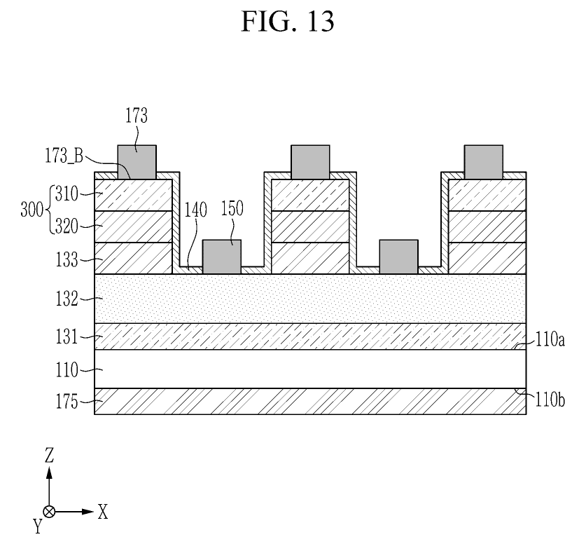

Hereinafter, referring to FIG. 13, a semiconductor pattern of a semiconductor device according to one or more example embodiments will be described.

FIG. 13 is a cross-sectional view illustrating a semiconductor device according to one or more example embodiments.

FIG. 13 illustrates various modified examples of a semiconductor device according to one or more example embodiments illustrated in FIGS. 1, 2, 3, 4, 5, 6, 7 and 8. One or more example embodiments illustrated in FIG. 13 is substantially similar to one or more example embodiments illustrated in FIGS. 1, 2, 3, 4, 5, 6, 7 and 8, so a duplicate description thereof will be omitted and the differences will be mainly explained. Additionally, the same drawing symbols are used for the same components as in the previous example embodiment.

Referring to FIG. 13, the gate electrode 150 of a semiconductor device according to one or more example embodiments may be positioned on the second semiconductor layer 132. The gate electrode 150 may be positioned on the upper surface of the second semiconductor layer 132. The gate electrode 150 may be electrically connected to the second semiconductor layer 132. The gate electrode 150 may be spaced apart from the third semiconductor layer 133. For example, the gate electrode 150 may be positioned on a side surface of the third semiconductor layer 133. The gate electrode 150 may overlap the third semiconductor layer 133 in the first direction (X direction), but example embodiments are not limited thereto.

A semiconductor device according to one or more example embodiments may include a plurality of third semiconductor layers 133 spaced apart in the first direction (X direction) on the second semiconductor layer 132. The plurality of third semiconductor layers 133 may be positioned directly on the second semiconductor layer 132. The gate electrode 150 may be positioned between the plurality of third semiconductor layers 133. The widths of each of the plurality of third semiconductor layers 133 in the first direction (X direction) may be substantially the same, but example embodiments are not limited thereto. The lengths of each of the plurality of third semiconductor layers 133 in the third direction (Z direction) may be substantially the same, but example embodiments are not limited thereto.

A semiconductor device according to one or more example embodiments may be a thyristor. For example, a semiconductor device according to one or more example embodiments may be a GTO thyristor (Gate Turn-Off thyristor) device with improved turn-off characteristics, or a thyristor with improved turn-on characteristics. In an example embodiment, the thyristor may be configured to handle high voltages and high currents by combining a PNP transistor and an NPN transistor through mutual current amplification, etc. For example, a thyristor may be used as a power device, but one or more example embodiments is not limited to this example embodiment and use of the thyristor may be varied.

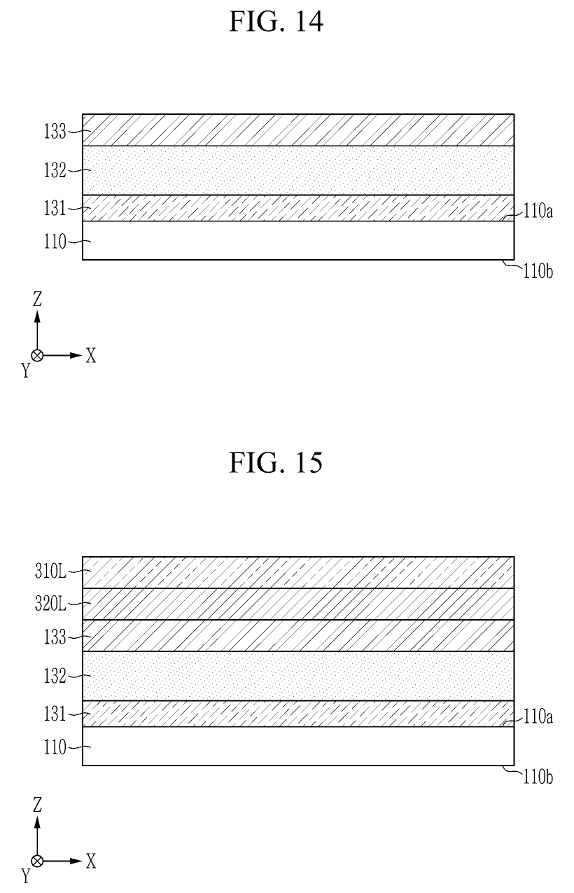

Hereinafter, a method for manufacturing a semiconductor device according to one or more example embodiments will be described, with reference to FIGS. 14, 15, 16 and 17.

FIGS. 14, 15, 16 and 17 are intermediate process cross-sectional views showing a method for manufacturing a semiconductor device according to one or more example embodiments.

Referring to FIG. 14, a first semiconductor layer 131, a second semiconductor layer 132, and a third semiconductor layer 133 may be formed on the substrate 110.

The substrate 110 may be a semiconductor substrate including SiC. For example, the substrate 110 may be made of a 4H SiC substrate. According to one or more example embodiments, the substrate 110 may be made of a 3C SiC substrate, a 6H SiC substrate, etc. The substrate 110 may be doped with first conductivity type impurities. For example, the first conductivity type impurity may be an n-type impurity. In other words, the substrate 110 may be doped as n-type. The substrate 110 may be heavily doped as n-type. The resistivity of the substrate 110 may be between about 0.005Ωcm and about 0.035Ωcm. The thickness of the substrate 110 may be from about 10 μm to about 700 μm. The material, doping type, doping concentration, resistivity, thickness, etc. of the substrate 110 are not limited thereto and may be variously changed according to one or more example embodiments.

The substrate 110 may include a first surface 110a and a second surface 110b opposing each other. For example, the first surface 110a of the substrate 110 may mean the upper surface of the substrate 110, and the second surface 110b of the substrate 110 may mean the lower surface of the substrate 110.

First, the first semiconductor layer 131 may be formed on the substrate 110. The first semiconductor layer 131 may be positioned on the first surface 110a of the substrate 110, i.e., the upper surface. The lower surface of the first semiconductor layer 131 may be in contact with the first surface 110a of the substrate 110. However, example embodiments are not limited thereto, and other layers may be additionally positioned between the substrate 110 and the first semiconductor layer 131. The first semiconductor layer 131 may be an epitaxial layer formed from the substrate 110 using an epitaxial growth method. The first semiconductor layer 131 may include SiC. For example, the first semiconductor layer 131 may include 4H SiC. The first semiconductor layer 131 may be doped as n-type. The first semiconductor layer 131 may be lightly doped as n-type. The doping concentration of the first semiconductor layer 131 may be lower than the doping concentration of the substrate 110. The doping concentration of the first semiconductor layer 131 may be between about 1*10¹⁵cm⁻³ and about 1*10¹⁷cm⁻³. The thickness of the first semiconductor layer 131 may be about 1 μm or more and about 13 μm or less.

Next, the second semiconductor layer 132 and the third semiconductor layer 133 may be sequentially formed on the first semiconductor layer 131.

A second semiconductor layer 132 may be formed on the first semiconductor layer 131. The second semiconductor layer 132 may be positioned on top of the first semiconductor layer 131. The second semiconductor layer 132 may include SiC. For example, the second semiconductor layer 132 may include 4H SiC. The second semiconductor layer 132 may be an epitaxial layer formed from the first semiconductor layer 131 using an epitaxial growth method. The second semiconductor layer 132 may have a second conductivity type different from the first conductivity type. The second conductivity type may be p-type. For example, the second semiconductor layer 132 may be doped as p-type. The second semiconductor layer 132 may be lightly doped as p-type. The doping concentration of the second semiconductor layer 132 may be about 1*10¹⁷cm⁻³ or more and about 1*10¹⁹cm⁻³ or less. The material, doping type, doping concentration, etc. of the second semiconductor layer 132 are not limited thereto and may be changed in various ways according to one or more example embodiments.

The third semiconductor layer 133 may be formed on the second semiconductor layer 132. The third semiconductor layer 133 may be positioned on top of the second semiconductor layer 132. The third semiconductor layer 133 may include SiC. For example, the third semiconductor layer 133 may include 4H SiC. The third semiconductor layer 133 may be an epitaxial layer formed from the second semiconductor layer 132 using an epitaxial growth method. The third semiconductor layer 133 may have a first conductivity type. The first conductivity type may be n-type. For example, the third semiconductor layer 133 may be doped as n-type. The doping concentration of the third semiconductor layer 133 may be less than or equal to the doping concentration of the first semiconductor layer 131, but example embodiments are not limited thereto. The material, doping type, doping concentration, etc. of the third semiconductor layer 133 are not limited thereto and may be changed in various ways according to one or more example embodiments.

Referring to FIG. 15, a second pattern material layer 320L and a first pattern material layer 310L may be formed on the third semiconductor layer 133.

First, the second pattern material layer 320L may be formed on the third semiconductor layer 133. The second pattern material layer 320L may be an epitaxial layer formed from the third semiconductor layer 133 using an epitaxial growth method. The second pattern material layer 320L may include a semiconductor material. The second pattern material layer 320L may include the same material as the first semiconductor layer 131, the second semiconductor layer 132, and the third semiconductor layer 133. For example, the second pattern material layer 320L may include a first element and a second element. Here, the first element may be Si and the second element may be C, but example embodiments are not limited thereto. For example, the second pattern material layer 320L may be SiₓC₁₋ₓ (0<x<1). In this case, the semiconductor material constituting the second pattern material layer 320L may have a second energy band gap (see BE2 of FIG. 2).

Next, the first pattern material layer 310L may be formed on the second pattern material layer 320L. The first pattern material layer 310L may be an epitaxial layer formed from the second pattern material layer 320L using an epitaxial growth method. The first pattern material layer 310L may include a semiconductor material. The work function of the first pattern material layer 310L may be greater than or equal to the work function of the anode electrode 173. The first pattern material layer 310L may include the same material as the first semiconductor layer 131, the second semiconductor layer 132, and the third semiconductor layer 133. For example, the first pattern material layer 310L may include a first element and a second element. Here, the first element may be Si and the second element may be C, but example embodiments are not limited thereto. For example, the first pattern material layer 310L may be SiₓC₁₋ₓ (0<x<1). In this case, the semiconductor material constituting the first pattern material layer 310L may have the first energy band gap (see BE1 of FIG. 2).

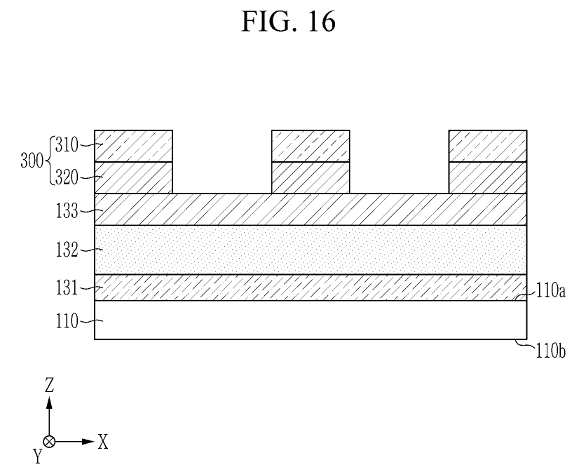

Referring to FIG. 16, the second pattern material layer 320L and the first pattern material layer 310L may be patterned to form the first pattern 310 and the second pattern 320. The process of patterning the second pattern material layer 320L and the first pattern material layer 310L may be performed using a dry etching or wet etching method, but example embodiments are not limited thereto. Accordingly, the upper surface of the third semiconductor layer 133 may be exposed.

Accordingly, a semiconductor device according to one or more example embodiments may include a plurality of semiconductor patterns 300 arranged spaced apart in the first direction (X direction) on the third semiconductor layer 133. The plurality of semiconductor patterns 300 may be positioned directly on the third semiconductor layer 133. The widths of each of the plurality of semiconductor patterns 300 in the first direction (X direction) may be substantially the same, but example embodiments are not limited thereto. The lengths of each of the plurality of semiconductor patterns 300 in the third direction (Z direction) may be substantially the same, but example embodiments are not limited thereto.

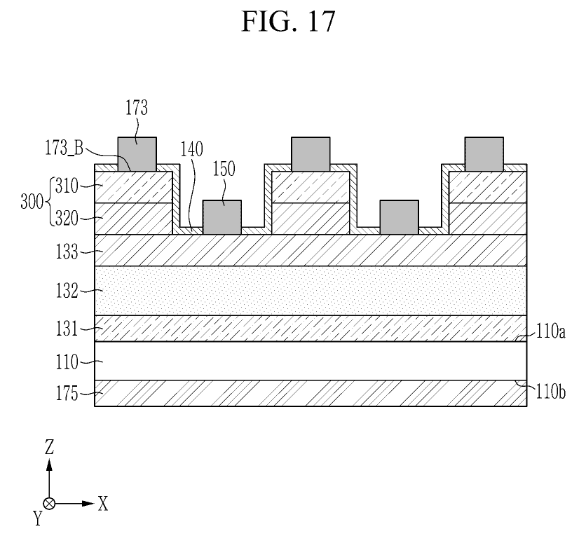

Referring to FIG. 17, an interlayer insulating layer 140 may be formed on the upper surface of the semiconductor pattern 300, the side surface of the semiconductor pattern 300, and the upper surface of the third semiconductor layer 133, an anode electrode 173 may be formed on the semiconductor pattern 300, a gate electrode 150 may be formed on the third semiconductor layer 133, and a cathode electrode 175 may be formed on the second surface 110b of the substrate 110.

The interlayer insulating layer 140 may be conformally formed on the upper surface of the semiconductor pattern 300, the side surface of the semiconductor pattern 300, and the upper surface of the third semiconductor layer 133. The thickness of the interlayer insulating layer 140 may be almost constant. The interlayer insulating layer 140 may be in contact with the semiconductor pattern 300 and the third semiconductor layer 133, but example embodiments are not limited thereto. The gate electrode 150 may penetrate a portion of the interlayer insulating layer 140 positioned on the third semiconductor layer 133. The anode electrode 173 may penetrate the interlayer insulating layer 140 positioned on the semiconductor pattern 300. Accordingly, a semiconductor device according to one or more example embodiments may be formed.

Although one or more example embodiments have been particularly shown and described in detail above, one or more example embodiments are not limited thereto, and it will be apparent to those skilled in the art that various changes in form and details may be made therein without departing from the spirit and scope of the following claims.

What is claimed is:

1. A semiconductor device comprising:
a first semiconductor layer having a first conductivity type;
a second semiconductor layer on the first semiconductor layer, the second semiconductor layer having a second conductivity type that is different from the first conductivity type;
a third semiconductor layer on the second semiconductor layer, the third semiconductor layer having the first conductivity type;
a gate electrode on the third semiconductor layer;
a semiconductor pattern on the third semiconductor layer, the semiconductor pattern having the second conductivity type;
an anode electrode on the semiconductor pattern; and
a cathode electrode on a lower surface of the first semiconductor layer,
wherein the semiconductor pattern comprises:
a first pattern on a lower surface of the anode electrode, the first pattern comprising a first semiconductor material having a first energy band gap; and
a second pattern between the first pattern and the third semiconductor layer, the second pattern comprising a second semiconductor material having a second energy band gap greater than the first energy band gap.

2. The semiconductor device of claim 1, wherein the third semiconductor layer comprises a material having a third energy band gap that is greater than or equal to the second energy band gap.

3. The semiconductor device of claim 2, wherein the semiconductor pattern further comprises:
a third pattern between the second pattern and the third semiconductor layer,
wherein the third pattern comprises a material having a band gap greater than the second energy band gap and less than or equal to the third energy band gap.

4. The semiconductor device of claim 1, wherein each of the first pattern and the second pattern comprises:
a first element which is a semiconductor element; and
a second element, and
wherein a content (at%) of the first element in the first pattern is greater than a content (at%) of the first element in the second pattern.

5. The semiconductor device of claim 4, wherein the third semiconductor layer comprises the first element and the second element,
wherein the content (at%) of the first element in the second pattern is greater than or equal to a content (at%) of the first element in the third semiconductor layer.

6. The semiconductor device of claim 4, wherein the content (at%) of the first element in the second pattern decreases as distance from the first pattern increases.

7. The semiconductor device of claim 4, wherein the first element comprises silicon (Si) and the second element comprises carbon (C).

8. The semiconductor device of claim 1, wherein the gate electrode is spaced apart from the semiconductor pattern.

9. The semiconductor device of claim 1, wherein the semiconductor pattern comprises a portion in which an energy band gap increases as distance from the lower surface of the anode electrode increases.

10. The semiconductor device of claim 1, wherein the third semiconductor layer comprises a first element which is a semiconductor element, and a second element,
wherein the second pattern comprises the first element, the second element, and a third element which is a semiconductor element different from the first element and the second element, and
wherein a content (at%) of the second element in the second pattern is less than or equal to a content (at%) of the second element in the third semiconductor layer.

11. The semiconductor device of claim 10, wherein the first element comprises silicon (Si), the second element comprises carbon (C), and the third element comprises germanium (Ge).

12. The semiconductor device of claim 10, wherein the first pattern comprises:
the first element which is the semiconductor element;
the second element; and
the third element, and
wherein a content (at%) of the third element in the first pattern is greater than a content (at%) of the third element in the second pattern.

13. The semiconductor device of claim 10, wherein a content (at%) of the first element in the second pattern is the same as the content (at%) of the second element in the second pattern.

14. A semiconductor device comprising:
a first semiconductor layer having a first conductivity type;
a second semiconductor layer on the first semiconductor layer, the second semiconductor layer having a second conductivity type that is different from the first conductivity type;
a third semiconductor layer on the second semiconductor layer, the third semiconductor layer having the first conductivity type;
a gate electrode on the third semiconductor layer;
a semiconductor pattern on the third semiconductor layer, the semiconductor pattern having the second conductivity type,
wherein the semiconductor pattern comprises:
a first element which is a semiconductor element; and
a second element;
an anode electrode on the semiconductor pattern; and
a cathode electrode on a lower surface of the first semiconductor layer,
wherein the semiconductor pattern comprises:
a first pattern; and
a second pattern between the first pattern and the third semiconductor layer,
wherein a content (at%) of the second element in the second pattern is greater than a content (at%) of the second element in the first pattern.

15. The semiconductor device of claim 14, wherein the first pattern and the second pattern each further comprise a third element, which is a semiconductor material different from the first element, and
wherein a content (at%) of the third element in the second pattern is smaller than a content (at%) of the third element in the first pattern.

16. The semiconductor device of claim 14, wherein the third semiconductor layer comprises the first element and the second element, and
wherein the content (at%) of the second element in the second pattern is less than or equal to a content (at%) of the second element in the third semiconductor layer.

17. The semiconductor device of claim 14, wherein the first element comprises silicon (Si) and the second element comprises carbon ©.

18. A semiconductor device comprising:
a substrate comprising a first surface and a second surface opposing each other;
a first semiconductor layer on the first surface of the substrate, the first semiconductor layer having a first conductivity type;
a second semiconductor layer on the first semiconductor layer, the second semiconductor layer having a second conductivity type that is different from the first conductivity type;
a third semiconductor layer on the second semiconductor layer, the third semiconductor layer having the first conductivity type and comprising silicon carbide (SiC);
a gate electrode on the third semiconductor layer;
a semiconductor pattern on the third semiconductor layer, the semiconductor pattern having the second conductivity type and comprising SiC;
an anode electrode on the semiconductor pattern; and
a cathode electrode on a lower surface of the first semiconductor layer,
wherein the semiconductor pattern comprises:
a first pattern having a first energy band gap and comprising Si at a first content (at%); and
a second pattern between the first pattern and the third semiconductor layer, the second pattern comprising Si at a second content (at%) smaller than the first content (at%).

19. The semiconductor device of claim 18, wherein the first energy band gap of the first pattern is smaller than a second energy band gap of the second pattern.

20. The semiconductor device of claim 18, wherein the third semiconductor layer comprises Si at a third content (at%) that is less than or equal to the second content (at%).
